(19) United States
(12) Patent Application Publication
(10) Pub. No.: US 2023/0274955 A1
(43) Pub. Date: Aug. 31, 2023

(54) SUBSTRATE HEAT-TREATING APPARATUS USING VCSEL

(71) Applicant: Viatron Co., Ltd., Gyeonggi-ido (KR)

(72) Inventors: Hyoung June Kim, Seoul (KR); Byung Kuk Kim, Gyeonggi-do (KR); Wang Jun Park, Gyeonggi-do (KR); Tae Hyeong Kim, Gyeonggi-do (KR); Bo Ram Lee, Gyeonggi-do (KR)

(21) Appl. No.: 18/008,103

(22) PCT Filed: Sep. 23, 2020
(86) PCT No.: PCT/KR2020/012827

§ 371 Date: Dec. 2, 2022

(30) Foreign Application Priority Data
Jun. 2, 2020 (KR) 10-2020-0066347

(51) Int. Cl. H01L 21/67; H01S 5/42; H01L 21/687; H01S 5/024

(52) U.S. Cl. CPC H01L 21/67115; H01S 5/423; H01L 21/68764; H01S 5/02423

(57) ABSTRACT

The present disclosure discloses a substrate heat-treatment apparatus using a VCSEL element, the substrate heat-treatment apparatus comprising: a process chamber in which a flat plate substrate to be heat-treated is mounted; and an irradiation module for irradiating a laser beam onto the flat plate substrate, the irradiation module including a sub-irradiation module which includes an element array plate, an element area which is mounted on an upper surface of the element array plate and on which the VCSEL element is mounted, and a terminal area on which an electrode terminal is mounted and which is located at the front or rear side of the element area, wherein, in the irradiation module, the element area and the terminal area are respectively arranged in the x-axis direction, and the element area and the terminal area are alternately arranged along the y-axis direction perpendicular to the x-axis direction.

### TECHNICAL FIELD

The present disclosure relates to a substrate heat-treating apparatus using VCSEL, which heats and heat-treats a flat substrate, such as a semiconductor wafer or a glass substrate, utilizing a laser irradiated from the VCSEL.

### BACKGROUND ART

A flat panel display device may be manufactured by depositing a low-temperature polycrystalline silicon thin layer on a flat substrate such as a glass substrate and then performing manufacturing processes such as a silicon thin film crystallization process, an ion implantation process, and an activation process.

The activation process may be performed in order to heal damage of the flat substrate caused by an ion implantation after the ion implantation process for source/drain regions of a transistor and to give electrical activation. In order to increase activation heat treatment efficiency and prevent an increase in a junction depth caused by diffusion in the high temperature activation process, the above activation process may be performed using a rapid heat treatment process in which the flat substrate is rapidly heated and cooled.

As the rapid heat treatment process, a rapid thermal process (RTP) in which heat treatment is performed at the temperature of 1,000 to 1,200° C. for several seconds using a halogen lamp may be used. In addition, the rapid heat treatment process may be used an irradiation method (flash lamp annealing: FLA) which irradiates a Xe-flash lamp in a range of μs˜ms and a method (laser spike annealing: LSA) by irradiating a laser to reduce the heat treatment time to a range of μs˜ms.

Meanwhile, in recent, a heat treatment process for heating a semiconductor wafer using a vertical cavity surface emitting laser (VCSEL) device has been developed. The above-mentioned heat treatment process is a method for heat-treating a semiconductor wafer by uniformly irradiating a laser beam on the semiconductor wafer using an irradiation module in which a plurality of VCSEL devices are disposed to cover a large surface region, and irradiate a laser beam. In the VCSEL device, a micro-emitter may emit a laser beam. The irradiation module utilizes the divergence of a laser beam emitted from the VCSEL device, and can uniformly heat the semiconductor wafer through overlapping of laser beams emitted from the VCSEL devices adjacent to each other. The irradiation module may constitute a sub-irradiation module including a plurality of VCSEL devices, and the plurality of sub-irradiation modules may be disposed up to an area covering the entire semiconductor wafer.

Recently, the above-mentioned heat treatment process requires a small temperature deviation and high temperature uniformity in response to the miniaturization of semiconductor technology. However, the currently employed heat treatment apparatus has a problem in that it is difficult to realize the required temperature uniformity due to various limitations.

### DISCLOSURE OF THE INVENTION

### Technical Problem

An object of the present disclosure is to provide a heat treatment apparatus capable of reducing temperature deviation of a flat substrate and increasing temperature uniformity during a heat treatment process.

In addition, another object of the present disclosure is to provide a heat treatment apparatus capable of efficiently cooling the heat in the device module, thereby extending the lifespan of the device module.

### Technical Solution

A substrate heat-treating apparatus using a VCSEL of the present disclosure includes a process chamber in which a flat substrate to be heat-treated is placed; and an irradiation module configured to irradiate a laser beam to the flat substrate, the irradiation module comprising a device array plate and sub-irradiation modules placed on an upper surface of the device array plate, each of sub-irradiation modules including a device region on which the VCSEL device is mounted and a terminal region located a front side or a rear side of the device region, wherein in the irradiation module, the device regions and the terminal regions are disposed in a x-axial direction, respectively, and the device regions and the terminal regions are alternately disposed in a y-axial direction perpendicular to the x-axial direction.

Also, in the sub-irradiation module, the device region may be formed in a quadrangular shape and the terminal regions may protrude from the other side of a front end and one end side of a rear end of the device region, and in the irradiation module, the device regions and the terminal regions may be sequentially disposed in the x-axial direction, respectively, and the device regions and the terminal regions may be alternately disposed in the y-axial direction.

In addition, in the sub-irradiation module, the device region may be formed in a quadrangular shape and the terminal region may be formed at the entire front end of the device region, and in the irradiation module, the device regions and the terminal regions may be sequentially disposed in the x-axial direction, respectively, and the device regions and the terminal regions may be alternately disposed in the y-axial direction.

Furthermore, the sub-irradiation module may be formed in a quadrangular shape, the terminal regions may be formed on the other side of the front end and one side of the rear end of the quadrangular shape, respectively, and have a rectangular shape having a predetermined length and a width corresponding to half the entire width of the quadrangular shape, the device region may be formed on a region excluding the terminal regions, and the irradiation module may include a region in which the device regions and the terminal regions are alternately arranged in the x-axial direction and a region in which only the device regions are arranged, and the device regions and the terminal regions may be alternately arranged in the y-axial direction.

In addition, the sub-irradiation modules may be formed to be independently supplied with power.

Also, the sub-irradiation module may include a device substrate on which the VCSEL device and an electrode terminal are mounted, and a cooling block coupled to a lower portion of the device substrate to cool the device substrate and the VCSEL device, wherein the cooling block may have a cooling passage, through which cooling water flows, formed therein.

Furthermore, the process chamber may include an outer housing, an inner housing disposed inside the outer housing and formed to have a height smaller than that of the outer housing, a beam transmitting plate placed above the inner housing, and a lower plate coupled to lower sides of the outer housing and the inner hosing, the process chamber may have an upper accommodation space formed inside the outer housing and above the inner housing to provide a space in which the flat substrate is placed, and a lower accommodation space formed between an outer surface of the inner housing and an inner surface of the outer housing, and the irradiation module may be positioned below the beam transmitting plate to irradiate a laser beam to a lower surface of the flat substrate.

In addition, the process chamber may further include a substrate support supporting an outer side of the flat substrate and formed to extend into the lower accommodation space, and the substrate heat-treating apparatus further include a substrate rotating module having an inner rotating means having a ring shape in which N poles and S poles are alternately arranged in a circumferential direction and being coupled to a lower portion of the substrate support within the lower accommodation space, and an outer rotating means placed outside the outer housing to face the inner rotating means and configured to generate a magnetic force to rotate the inner rotating means.

Also, the substrate heat-treating apparatus may further include a substrate rotating module configured to support and rotate the flat substrate.

Furthermore, the irradiation module may be formed such that the device region is located at a center of the flat substrate.

In addition, the irradiation module may be formed such that the terminal region is located at a center of the flat substrate.

### Advantageous Effects

The substrate heat-treating apparatus using the VCSEL of the present disclosure optimizes the arrangement of the sub-irradiation modules to uniformly irradiate a laser beam to the flat substrate, thus having the effect of reducing the temperature deviation and increasing the temperature uniformity of the flat substrate.

In addition, the substrate heat-treating apparatus using the VCSEL of the present disclosure rotates the flat substrate to uniformly irradiate a laser beam to the flat substrate, thus having the effect of reducing the temperature deviation and increasing the temperature uniformity of the flat substrate.

Also, the substrate heat-treating apparatus using the VCSEL of the present disclosure may independently apply power to each of the sub-irradiation modules to increase the uniformity of light energy by an irradiated laser beam.

Furthermore, the substrate heat-treating apparatus using the VCSEL of the present disclosure independently control the power applied to the sub-irradiation modules, thus having the effect of further improving the temperature uniformity of the flat substrate.

In the substrate heat-treating apparatus using the VCSEL of the present disclosure, in addition, the transparent window is disposed at the upper or lower portion the process chamber in which the flat substrate is heat treated, and the irradiation module is provided outside the process chamber to separate the inside of the process chamber from the heating light source, so it is possible to easily control the vacuum atmosphere inside the process chamber.

### BRIEF DESCRIPTION OF THE DRAWINGS

FIG. 1 is a view showing a structure of a substrate heat-treating apparatus using a VCSEL, according to one embodiment of the present disclosure;

FIG. 2 is a partial perspective view of an irradiation module of FIG. 1;

FIG. 3 is a vertical cross-sectional view taken along line A-A of FIG. 2;

FIG. 4 is a perspective view of an irradiation module according to another embodiment of the present disclosure;

FIG. 5 is a perspective view of an irradiation module according to yet another embodiment of the present disclosure;

FIG. 6A and FIG. 6B are plane views of the irradiation modules of FIG. 2 mounted on the substrate heat-treating apparatus according to one embodiment of the present disclosure;

FIG. 7 shows the evaluation results of heat flux in an axial direction when a flat substrate is stationary in the substrate heat-treating apparatuses of FIG. 6A and FIG. 6B;

FIG. 8 shows the evaluation results of heat flux when the flat substrate is being rotated in the substrate heat-treating apparatuses of FIG. 6A and FIG. 6B;

FIG. 9 shows temperature distribution evaluation results depending on a rotation speed of the flat substrate in the substrate heat-treating apparatus of FIG. 6A;

FIG. 10 shows temperature distribution evaluation results depending on a rotation speed of the flat substrate in the substrate heat-treating apparatus of FIG. 6B;

FIG. 11 is a plane view of an irradiation module mounted on a substrate heat-treating apparatus according to a comparative example;

FIG. 12 shows evaluation results of heat flux in an axial direction when a flat substrate is stationary in the substrate heat-treating apparatus of FIG. 11; and

FIG. 13 shows evaluation results of heat flux in an axial direction when the flat substrate is being rotated in the substrate heat-treating apparatus provided with the irradiation module according to a comparative example.

### BEST MODE FOR CARRYING OUT THE INVENTION

Hereinafter, a substrate heat-treating apparatus using a VCSEL, according to the present disclosure is described in detail with reference to embodiments and the accompanying drawings.

First, a structure of a substrate heat-treating apparatus using a VCSEL, according to one embodiment of the present disclosure is described.

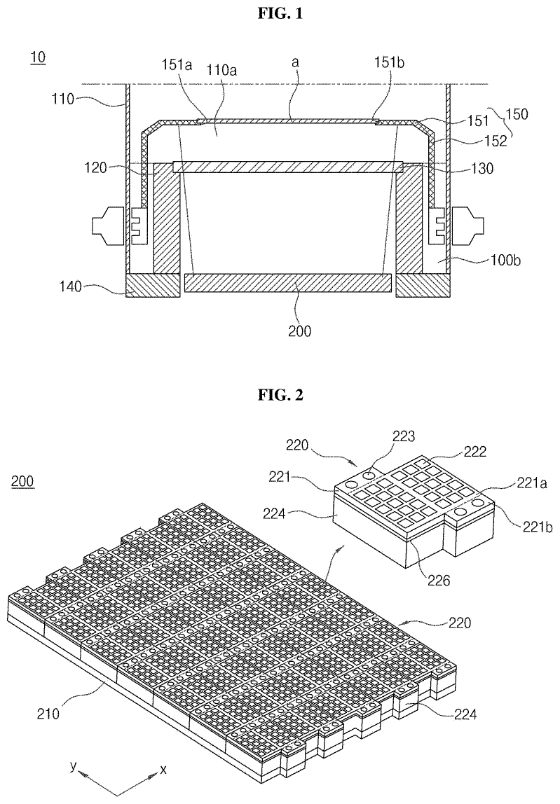

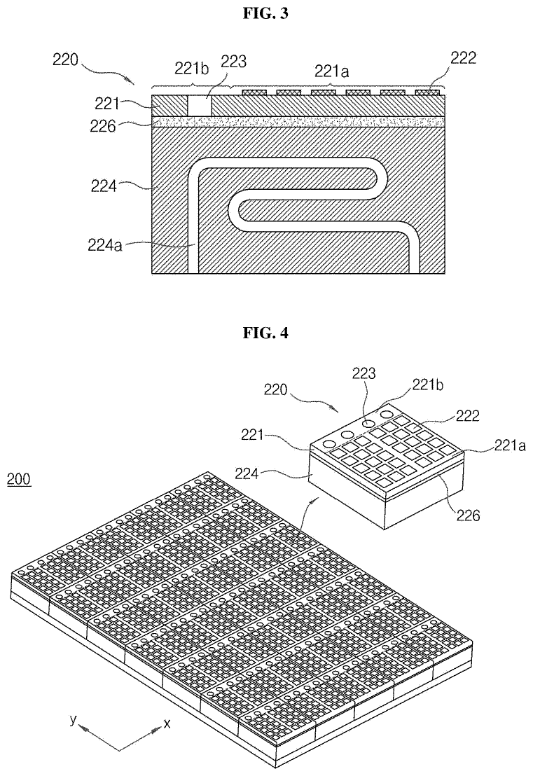

FIG. 1 is a view showing a structure of a substrate heat-treating apparatus using a VCSEL, according to one embodiment of the present disclosure. FIG. 2 is a partial perspective view of an irradiation module of FIG. 1. FIG. 3 is a vertical cross-sectional view taken along line A-A of FIG. 2.

Referring to FIG. 1 to FIG. 3, a substrate heat-treating apparatus 10 using VCSEL, according to one embodiment of the present disclosure may include a process chamber 100 and an irradiation module 200. In addition, the substrate heat-treating apparatus 10 may further includes a substrate rotating module 300.

In the substrate heat-treating apparatus 10, a manufacturing process such as a silicon thin film crystallization process, an ion implantation process, or an activation process for the flat substrate a may be performed.

The substrate heat-treating apparatus 10 may irradiate a laser beam, which is generated from the irradiation module 200 including the VCSEL device, to the flat substrate a to heat the flat substrate a. Here, the flat substrate a may be a semiconductor wafer or a glass substrate. In addition, the flat substrate a may be a flexible substrate such a resin film. Further, the flat substrate a may include various elements or conductive patterns formed on a surface thereof or therein.

The process chamber 100 may include an outer housing 110, an inner housing 120, a beam transmitting plate 130, a lower plate 140, and a substrate support 150. The process chamber 100 may provide a space in which the flat substrate a is accommodated and heat-treated. The flat substrate a may be supported by the substrate support 150 inside the process chamber 100. The process chamber 100 is configured to allow a laser beam generated by the irradiation module 200 placed at an outside thereof to be irradiated to an inside thereof. That is, below the substrate support 150, the process chamber 100 may be provided with a beam irradiation window through which a laser beam is transmitted. Meanwhile, in the process chamber 100, the beam irradiation window may be placed above the substrate support 150.

Referring to FIG. 1, on the other hand, although not specifically depicted, the process chamber 100 may further include various process means provided at an upper portion thereof and necessary for a heat treatment process. For example, a sputtering means may be provided at the upper portion of the process chamber 100.

The outer housing 110 is formed in an internally hollow barrel shape, and may be formed in a cylindrical shape or a quadrangular barrel shape. The outer housing 110 may be formed in a shape having a horizontal cross-sectional area greater than the area of the flat substrate a to be heat-treated therein.

On the other hand, the outer housing 110 may be formed to have a structure that extends outward from a predetermined height depending on the heat treatment process and a size of the flat substrate a. In addition, although an upper structure is not specifically illustrated, the outer housing 110 may be formed in various shapes configured to accommodate or support a process means located thereon.

The inner housing 120 is formed in an internally hollow barrel shape, and may be formed in a cylindrical shape, a quadrangular barrel shape, a pentagonal barrel shape, or a hexagonal barrel shape. The inner housing 120 may have an outer diameter or an outer width smaller than an inner diameter or an inner width of the outer housing 110. In addition, the inner housing 120 may be formed to have a height smaller than that of the outer housing 110. Also, the inner housing 120 may be formed to have a height such that its upper side is positioned below the flat substrate a placed inside the process chamber 100. Further, the inner housing 120 may be formed to have a diameter or a width greater than a diameter or a width of the flat substrate a placed thereabove. In addition, the inner housing 120 may be formed to have a horizontal area greater than that of the flat substrate a. Accordingly, an upper accommodation space 100a in which the flat substrate a is placed may be formed above the inner housing 120. That is, the upper accommodation space 100a is formed above the inner housing 120 inside the outer housing 110, and provides a space in which the flat substrate a is placed.

In addition, the flat substrate a may be placed in the upper accommodation space 100a so that an entire area is exposed when viewed from a bottom of a lower housing. In addition, the inner housing 120 may be coupled to the outer housing 110 such that a lower side of the inner housing is positioned at approximately the same height as a lower side of the outer housing 110. A lower accommodating space 100b may be formed between an outer side surface of the inner housing 120 and an inner side surface of the outer housing 110. The upper accommodation space 100a and the lower accommodation space 100b may be shielded from the outside by the outer housing 110, the inner housing 120, and the lower plate 140 to be maintained under a vacuum or process gas atmosphere.

The beam transmitting plate 130 is coupled to an upper side of the lower housing, and may be placed below the flat substrate a. The beam transmitting plate 130 may be formed of a transparent plate, such as quartz or glass, through which a laser beam passes. The beam transmitting plate 130 allows a laser beam to pass therethrough and to be irradiated to a lower surface of the flat substrate a. More specifically, the beam transmitting plate 130 allows a laser beam incident through a lower surface thereof from the inside of the lower housing to be irradiated to the lower surface of the flat substrate a. The beam transmitting plate 130 may have an area larger than that of the flat substrate a. For example, the beam transmitting plate 130 may be formed to have a diameter or a width greater than a diameter or a width of the flat substrate a. Preferably, the beam transmission plate 130 may be formed to have a diameter or a width of 1.1 times or more than that of the flat substrate a. In this case, the beam transmitting plate 130 enables a laser beam to be irradiated to the entire lower surface of the flat substrate a.

Meanwhile, the beam transmitting plate 130 is disposed at an upper portion of the process chamber 100, for example, at an upper portion the outer housing 110, and may be formed such that a laser beam, that is incident through an upper face thereof from the upper portion of the outer housing 110, is irradiated to the upper surface of the flat substrate a.

The lower plate 140 may be coupled to the lower sides of the outer housing 110 and the inner housing 120 to seal a lower portion of the space between the outer housing 110 and the inner housing 120. That is, the lower plate 140 may seal the lower portion of the lower accommodation space 100b. The lower plate 140 may be formed as a circular ring or a quadrangular ring having a predetermined width. The lower plate 140 may be formed in various shapes according to a lower planar shape of the lower accommodation space 100b.

The substrate support 150 may include an upper support 151 and a connection support 152. The substrate support 150 may be located above the lower housing to support a lower outer side of the flat substrate a so that the lower surface of the flat substrate a is exposed. In addition, the substrate support 150 may extend into the lower accommodation space 100b to be coupled to the substrate rotating module 300. The substrate support 150 may rotate the flat substrate a in response to an operation of the substrate rotating module 300.

The upper support 151 is provided with a substrate exposing hole 151a formed at an inner part thereof, and may be formed in a ring shape having a predetermined width. The upper supporter 151 may support the lower outer side of the flat substrate a while exposing the lower surface of the flat substrate a. The upper support 151 may be formed to have a diameter or a width greater than a diameter or a width of the flat substrate a.

The substrate exposing hole 151a may be formed by passing through the upper support 151 from an upper surface to a lower surface at a center thereof. The substrate exposing hole 151a may be formed to have a predetermined area such that a region of the lower surface of the flat substrate a requiring heat treatment is entirely exposed therethrough. The substrate exposing hole 151a may have a substrate supporting jaw 151b formed at an upper end thereof to enable the flat substrate a to be stably supported.

The connection support 152 is formed in an approximately cylindrical shape with opened upper and lower sides, and may be formed in a shape corresponding to the shape of the inner housing 120. For example, the lower support may be formed in a cylindrical shape corresponding to the inner housing when the inner housing 120 is formed in a cylindrical shape. The connection support 152 may be positioned over the upper accommodation space 100a and the lower accommodation space 100b. An upper portion of the connection support 152 may be coupled to an outer side of the upper support 151, and a lower portion may be extended into the lower accommodation space 100b to be coupled to the substrate rotation module 300. Accordingly, the connection support 152 may rotate the upper support 151 and the flat substrate a while being rotated by the substrate rotation module 300.

The irradiation module 200 may include a device array plate 210 and sub-irradiation modules 220. The irradiation module 200 may be positioned outside the process chamber 100 to irradiate a laser beam to a surface of a transparent substrate a through the beam transmitting plate 130. The irradiation module 200 may be positioned below or above the process chamber 100 depending on the positions of the beam transmitting plate 130 installed in the process chamber 100 and the flat substrate a. For example, the irradiation module 200 may be located under the beam transmitting plate 130 inside the inner housing 120. Accordingly, the irradiation module 200 may be positioned below the beam transmitting plate 130 at the outside of the process chamber 100 to irradiate a laser beam to the lower surface of the flat substrate a.

In the irradiation module 200, the plurality of sub-irradiation modules 220 may be arranged on an upper surface of the device array plate 210 in a lattice form. Referring to FIG. 2, the sub-irradiation modules 220 may be arranged on the upper surface of the device array plate 210 in a x-direction and a y-direction to be arranged in a lattice shape. Hereinafter, the x-direction is expressed in one side and the other side or one end and the other end, and the y-direction is expressed in a front side and a rear side or a front end and a rear end. In addition, the x-direction is expressed in a width or a widthwise direction, and the y-direction is expressed in a length or a longitudinal direction.

The device array plate 210 may be formed in a plate shape having predetermined area and thickness. The device array plate 210 may be preferably formed to correspond to the shape and area of the flat substrate a. The device array plate 210 may be formed of a thermally conductive ceramic material or metallic material. The device array plate 210 may function to radiate heat generated from the VCSEL device.

The sub-irradiation module 220 may include a device substrate 221, VCSEL devices 222, an electrode terminal 223, and a cooling block 224. The plurality of the sub-irradiation modules 220 may be arranged and positioned on the device array plate 210 in a grid direction. The sub-irradiation module 220 may be arranged on a region of a surface of the device array plate 210 which is required for irradiating a laser beam to an irradiation region of the flat substrate a. The device substrate 221 may be coupled to the cooling block 224 by a separate adhesive layer 226.

The sub-irradiation module 220 is formed by arranging the plurality of VCSEL devices 222 in the x-axial direction and the y-axial direction. Although not specifically illustrated, the sub-irradiation module 220 may include a light emitting frame (not shown) for securing the VCSEL devices 222 and a power line (not shown) for supplying power to the VCSEL devices 222. The sub-irradiation module 220 may be formed such that the same power is applied to the entire VCSEL devices 222. In addition, the sub-irradiation module 220 may be formed such that different powers are applied to each of the VCSEL devices 222.

The sub-irradiation module 220 may include a device region 221a on which the VCSEL devices 222 are mounted and a terminal region 221b on which the electrode terminal 223 is mounted. The device region 221a may be formed in a quadrangular shape, and the terminal regions may be formed to protrude from the other side of a front end and one side of a rear end of the device region 221a, respectively. The terminal regions may be formed on a half region in the other side direction at the front end of the device region 221a and on a half region in one side direction at the rear end of the device region 221a, respectively. That is, the terminal region may be formed to have a width corresponding to half the width of the device region 221a. In addition, the sub-irradiation module 220 may be formed to have linear-shaped one side and the linear-shaped other side. The terminal region may be formed such that a length thereof is shorter than a length of the device region 221a. A length of the sub-irradiation module 220 is approximately 30 mm, and a length of the terminal region is formed as short as possible, and is formed to be 10 mm, preferably may be less than 7 mm. The terminal regions may be formed to have the same length on the front side and rear side.

When arranged in the y-axial direction, the terminal region located at the other side of the front end of the sub-irradiation module 200 and the termina region located at one side of the rear end of the adjacent sub-irradiation module 200 may be adjacent to each other in the x-axial direction. In the sub-irradiation module 220, the device regions 221a and the terminal regions may be linearly arranged in the x-axial direction, respectively, and the device regions 221a and the terminal regions may be alternately arranged in the y-axial direction. The sub-irradiation modules 220 may be disposed such that a pitch between the sub-irradiation modules 220 adjacent thereto in the y-axial direction and/or the x-axial direction is minimized. In addition, the sub-irradiation modules 220 may be arranged to have a pitch therebetween of up to 2 mm.

Accordingly, in the irradiation module 200, the device regions 221a and the terminal regions of the sub-irradiation modules 220 may be sequentially arranged in the x-axial direction, respectively, and the device regions 221a and the terminal regions may be alternately arranged in the y-axial direction

The device substrate 221 may be formed of a general substrate used for mounting an electronic device. The device substrate 221 may be divided into the device region 221a on which the VCSEL devices 222 are mounted and the terminal region 221b on which the terminal 223 is mounted. On the device region 221a, the plurality of VCSEL devices 222 may be arranged and mounted in a lattice shape. The terminal region 221b is positioned to be adjacent to the device region 221a, and the plurality of electrode terminals may be mounted on this terminal region.

In the device substrate 221, the device region 221a may be formed in a quadrangular shape, and the terminal regions 221b may be formed to protrude from the other side of a front end and one side of a rear end of the device region 221a, respectively. The terminal regions 221b may be formed in a half of the other direction at a front end of the device region 221 and in a half of the one direction at a rear end of the device region 221. In addition, one side and the other side of the device substrate 221 may be formed to have a linear shape.

As the VCSEL device 222, a general VCSEL device 222 irradiating a laser beam may be employed. For example, the VCSEL device 222 may be formed of a device oscillating a surface-emitting laser. The VCSEL device 222 may be formed to have a quadrangular shape, preferably a square shape or a rectangular shape in which the ratio of width to length does not exceed 1:2. The VCSEL device 222 is manufactured as a cubic-shaped chip, and a high-power laser beam is oscillated from one surface. Since the VCSEL device 222 oscillates a high-power laser beam, compared to the conventional halogen lamp, this device can increase the rate of temperature increase of the flat substrate a and has a relatively long lifespan.

On the device region 221a, the plurality of the VCSEL devices 222 may be arranged on the upper surface of the device substrate 221 in the x-direction and the y-direction to be arranged in a lattice shape. An appropriate number of the VCSEL devices 222 may be placed at appropriate intervals according to the area of the device region 221a and the amount of energy of a laser beam irradiated to the flat substrate a. In addition, the VCSEL devices 222 may be positioned at an interval by which uniform energy is irradiated when a laser beam emitted from one VCSEL device overlaps a laser beam of the adjacent VCSEL device 222. At this time, the VCSEL devices 222 may be placed such that sides of the adjacent VCSEL devices 222 are in contact with each other and there is no separation distance therebetween.

The plurality of the electrode terminals 223 may be formed in the terminal region 221b of the device substrate 221. The electrode terminal 223 includes a +terminal and a −terminal, and may be electrically connected to the VCSEL device 222. Although not specifically illustrated, the electrode terminal 223 may be electrically connected to the VCSEL device 222 in various ways. The electrode terminal 223 may supply power required for driving the VCSEL device 222.

Although not specifically illustrated, the electrode terminal 223 may include a terminal hole to allow a terminal line connected to the VCSEL device 222 to be extended below the device substrate 221.

The cooling block 224 may be formed to have a planar shape corresponding to a planar shape of the device substrate 221 and a predetermined height. The cooling block 224 may be formed of a thermally conductive ceramic material or metallic material. The cooling block 224 may be coupled to a lower surface of the device substrate 221 by a separate adhesive layer. The cooling block 224 may radiate heat generated from the VCSEL device 222 mounted on a surface of the device substrate 221 downward. Accordingly, the cooling block 224 may cool the device substrate 221 and the VCSEL device 222.

A cooling passage 224a through which cooling water flows may be formed in the cooling block 224. The cooling passage 224a may have an inlet port and an outlet port formed on a lower surface of the cooling block, and may be formed in the cooling block 224 as various types of flow passages.

The substrate rotating module 300 may include an inner rotating means 310 and an outer rotating means 320. The substrate rotating module 300 may rotate the substrate support 150 in a horizontal direction in a non-contact manner. More specifically, the inner rotating means 310 may be coupled to a lower portion of the substrate support 150 in the lower accommodation space 100b of the process chamber 100. In addition, the outer rotating means 320 may be positioned to face the inner rotating means 310 at the outside of the process chamber 100. The outer rotating means may rotate the inner rotating means 310 in a non-contact manner using a magnetic force.

The inner rotating means 310 may be formed to have the same structure as a rotor of a motor. For example, the inner rotating means 310 may be formed as a magnet structure that is formed in a ring shape as a whole and has N poles and S poles alternately arranged in a circumferential direction. The inner rotating means 310 may be coupled to the lower portion of the substrate support 150, that is, the connection support 152. At this time, the inner rotating means 310 may be positioned to be spaced upward apart from an upper portion of the lower plate 140. Meanwhile, although not specifically illustrated, the inner rotating means 310 may be supported by a separate support means such that vibration is prevented during rotation or it can be rotated smoothly. For example, a lower portion of the inner rotating means 310 may be supported by a support bearing or roller.

The outer rotating means 320 may be formed to have the same structure as a stator of a motor. For example, the outer rotating means 320 may include an iron core formed in a shape of ring and a conducting wire wound around the iron core. The outer rotating means 320 may rotate the inner rotating means 310 with a magnetic force generated by power supplied to the conducting wire. The outer rotating means 320 may be placed outside the outer housing 110 so as to face the inner rotating means 310 with respect to the outer housing 110. In other words, the outer rotating means 320 may be placed outside the outer housing with the respect to the outer housing 110 at the same height as the inner rotating means 310.

In addition, the irradiation module 200 of the present disclosure may include a sub-irradiation module 220 formed in various shapes.

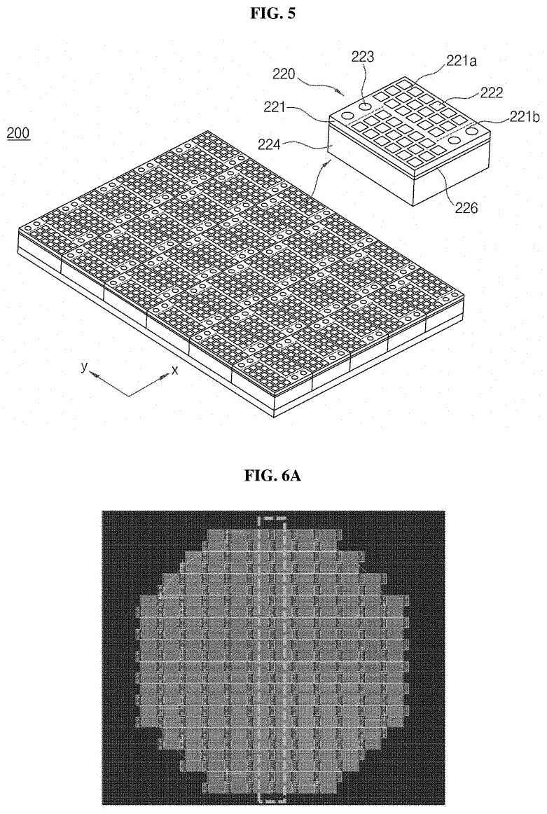

FIG. 4 is a perspective view of an irradiation module according to another embodiment of the present disclosure. FIG. 5 is a perspective view of an irradiation module according to yet another embodiment of the present disclosure;

Referring to FIG. 4, the sub-irradiation module 220 of the irradiation module 200 according to another embodiment of the present disclosure may be formed in a quadrangular shape as a whole. The sub-irradiation module 220 may be formed in a rectangular shape. In addition, in the sub-irradiation module 220, the device region 221a is formed in a quadrangular shape having an entire width and a predetermined length, and the terminal region 221b is formed at the entire front end of the device region 221a. In addition, the above-mentioned terminal region 221b is not formed at the rear end of the sub-irradiation module 220. That is, the terminal region 221b is formed to have the same width as the device region 221a and is positioned at the front end of the device region 221a. Also, the terminal region 221b may be formed to have a length smaller than that of the device region 221a. In addition, one side and the other side of the device irradiation module may be formed in a linear shape.

In the irradiation module 200, when the sub-irradiation modules 220 are arranged in the y-axial direction, the terminal region 221b positioned at the front end may become in contact with the device region 221a of the sub-irradiation module 220 positioned in front thereof.

Accordingly, in the irradiation module 200, the device regions 221a and the terminal regions 221b of the sub-irradiation modules 220 are sequentially arranged in the x-axial direction, respectively, and the device regions 221a and terminal regions 221b may be alternately arranged in the y-axial direction.

In addition, the irradiation module 200 may be formed such that the device region 221a is positioned at a center of the flat substrate a in relation to the flat substrate a positioned thereabove. In addition, the irradiation module 200 may be formed such that the terminal region 221b is located at the center of the flat substrate a. Referring to the evaluation results below, the irradiation module 200 can heat the flat substrate a more uniformly when the device region 221a is formed to be positioned at the center of the flat substrate a.

Referring to FIG. 5, the sub-irradiation module 220 of the irradiation module 200 according to yet another embodiment of the present disclosure may be formed in an approximately quadrangular shape. The sub-irradiation module 220 may be formed in a quadrangular shape. In addition, on the sub-irradiation module 220, the terminal regions 221b may be formed on the other side of the front end and one side of the rear end of the quadrangular shape, respectively, and have a rectangular shape having a predetermined length and a width corresponding to half the entire width of the sub-irradiation module. That is, the terminal region 221b may be formed to have a width corresponding to half the width of the sub-element module. The terminal regions 221b may be disposed in a diagonal direction on the rectangular shape. In the sub-irradiation module, a region excluding the terminal regions 221b may be formed as the device region 221a.

In addition, one side and the other side of the device irradiation module may be formed in a linear shape. The terminal region 221b may be formed to have a length shorter than a length of the device region 221a. The terminal regions 221b may be formed to have the same length on the front side and the rear side, respectively.

In the irradiation module, when the sub-irradiation modules 220 are arranged in the y-axial direction, the terminal region 221b positioned at one side of the front end may become in contact with the device region 221a positioned at one side of the rear end of the sub-irradiation module 220 positioned in front thereof. When the sub-irradiation modules 220 are arranged in the y-axial direction, the terminal region 221b positioned at the other side of the rear end may become in contact with the device region 221a positioned at the other side of the front end of the sub-irradiation module 220 positioned in front thereof.

In addition, in the sub-irradiation module 220, the device regions 221a and the terminal regions 221b are alternately arranged in the x-axial direction on a region where the terminal regions 221b are formed with respect to the y-axial direction, and the terminal regions 221a may be linearly arranged in the x-axial direction on a region where the device region 221b is not formed.

Accordingly, the irradiation module 200 includes a region in which the device regions 221a and the terminal regions 221b are alternately arranged in the x-axial direction and a region in which only the device regions 221a are arranged, and the device regions 221a and the terminal regions 221b may be alternately arranged in the y-axial direction.

Next the operation of the substrate heat-treating apparatus using the VCSEL device 222 according to one embodiment of the present disclosure is described below. Hereinafter, the operation of the substrate heat-treating apparatus will be mainly described based on the operation of the irradiation module 200. In addition, the following description will focus on the case where the flat substrate a is a semiconductor wafer.

When the irradiation module 200 of the present disclosure is formed to have the configuration shown in FIG. 2 or FIG. 4, as described above, the device regions 221a and the terminal regions 221b of the sub-irradiation modules 220 are sequentially arranged in the x-axial direction, respectively, and the device regions 221a and the terminal regions 221b are alternately arranged in the y-axial direction. That is, in the irradiation module 200, when the sub-irradiation modules 220 are arranged in the x-axial direction and the y-axial direction, the terminal regions 221b are arranged with a predetermined width in x-axial direction, and the terminal regions and the device regions 221a are alternately arranged in the y-axial direction. In addition, in the irradiation module 200, the terminal region 221b is formed to have a relatively small length. The sub-irradiation module 220 has a square or rectangular shape as a whole.

In the irradiation module 200, overlapping of laser beams irradiated from the VCSEL devices 222 occurs mainly in the terminal regions 221b, and forms one-dimensional linearity according to the arrangement of the terminal regions 221b.

In the irradiation module 200, the intensity deviation of a laser beam caused by the overlap in the terminal region 221b is approximately 0.25%. However, in the irradiation module 200, the regions on which overlapping occurs are one-dimensionally linear, and do not coincide with a circumferential direction of the semiconductor wafer. Accordingly, when the irradiation module 200 irradiates a laser beam to the semiconductor wafer, it the semiconductor wafer is simultaneously rotated, the intensity deviation of a laser beam may be further reduced. When the semiconductor wafer is rotated, the reduction rate of the intensity deviation of a laser beam may be determined by the rotation speed of the semiconductor wafer. For example, when the rotation speed of the semiconductor wafer is 200 rpm, the intensity deviation of a laser beam is reduced to 0.05%. Here, the intensity deviation of a laser beam has an effect on the degree of heating of the semiconductor wafer, and may have a direct effect on the temperature uniformity of the semiconductor wafer.

In addition, when the irradiation module 200 of the present disclosure is formed to have the configuration shown in FIG. 5, as described above, a region on which the device regions 221a and the terminal regions 221b are alternately arranged in the x-axial direction and a region on which only the device regions 221a are arranged are provided, and the device regions 221a and the terminal regions 221b may be alternately arranged in the y-axial direction. In the irradiation module 200, the terminal regions 221b may be positioned in a diagonal direction on the sub-irradiation module 220. Compared to the irradiation module 200 of FIG. 2 or FIG. 4, the irradiation module 200 may increase the number of the VCSEL devices 222 for each sub-irradiation module 220 to increase the output of a laser beam per unit area. In addition, in the irradiation module 200, the device substrate 221 may be easily coupled to the cooling block 224 in each sub-irradiation module 220. In the irradiation module 200, since the overlapped terminal regions 221b are not arranged in a straight line in the x-axial direction, but are arranged in a zigzag manner, compared to FIG. 2 and FIG. 4, the temperature deviation is shown as being relatively high. For example, the irradiation module 200 has the intensity deviation of 0.34%.

In addition, in the irradiation module 200, the overlapped terminal regions 221b are arranged in a straight line in the x-axial direction differently from the circumferential direction of the semiconductor wafer. Accordingly, in the irradiation module 200, when the semiconductor wafer is rotated, non-uniformity caused by overlapping is improved, and the intensity deviation can be reduced to 0.05%. Therefore, the irradiation module 200 may increase the irradiation uniformity of a laser beam on the surface of the semiconductor wafer.

If the semiconductor wafer is rotated, when the irradiation module 200 irradiates a laser beam, the number of VCSEL devices participating in laser beam irradiation for a specific region of the semiconductor wafer may be increased. Therefore, it is possible to significantly reduce the deviation of a laser beam irradiated to the semiconductor wafer by the output deviation between micro-emitters constituting the VCSEL device 222 constituting the irradiation module 200 and the output deviation between the VCSEL devices 222. In addition, even when the micro-emitter fails due to operation for long-time, the irradiation module 200 can maintain the irradiation uniformity of a laser beam.

In addition, the irradiation module 200 may be controlled by independently supplying power to each sub irradiation module 220 or to each sub irradiation module 220 located in a plurality of divided regions. In general, since the semiconductor wafer has a large amount of heat loss at an edge portion thereof during a heat treatment process, it may be necessary to supply a relatively large amount of energy. The irradiation module 200 may increase the power supplied to the sub-irradiation module 220 irradiating a laser beam to the edge portion of the semiconductor wafer. In addition, in the irradiation module 200, since the terminal regions 221b are arranged in the x-axial direction and overlap in a one-dimensional pattern, it is possible to reduce the output difference between the sub-irradiation modules 220 when the semiconductor wafer is rotated. Therefore, the irradiation module 200 may heat the semiconductor wafer more evenly. That is, the irradiation module 200 can effectively eliminate the increase in intensity deviation of a laser beam caused by the output difference between the sub-irradiation modules 220. The irradiation module 200 can uniformly heat the entire semiconductor wafer without adjusting the separation distance between the sub-irradiation modules 220 located at the edge and the center and the semiconductor wafer. In addition, the irradiation module 200 can uniformly heat the flat substrate a, regardless of the area of the flat substrate a, without changing an arrangement interval and the number of sub-irradiation modules 220.

Below, evaluation results of the substrate heat-treating apparatus according to embodiments of the present disclosure will be described.

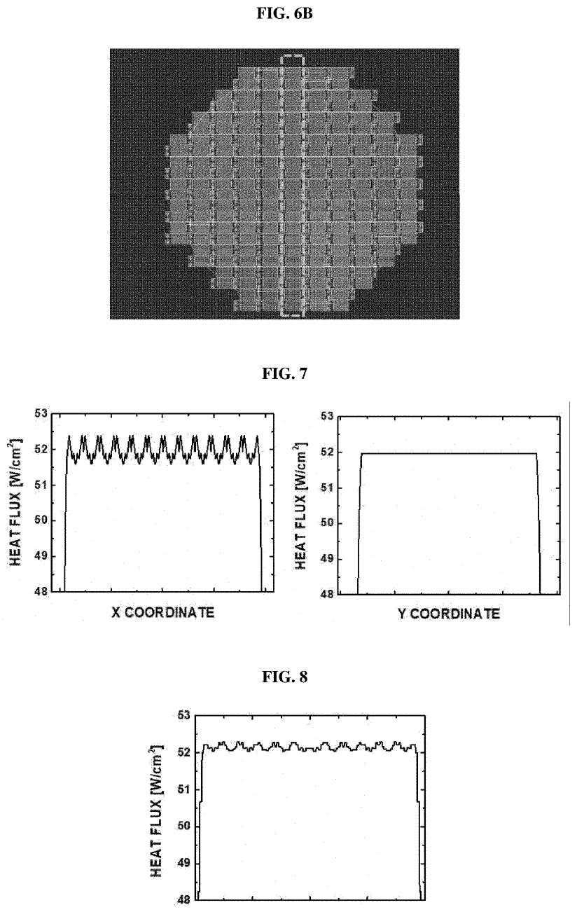

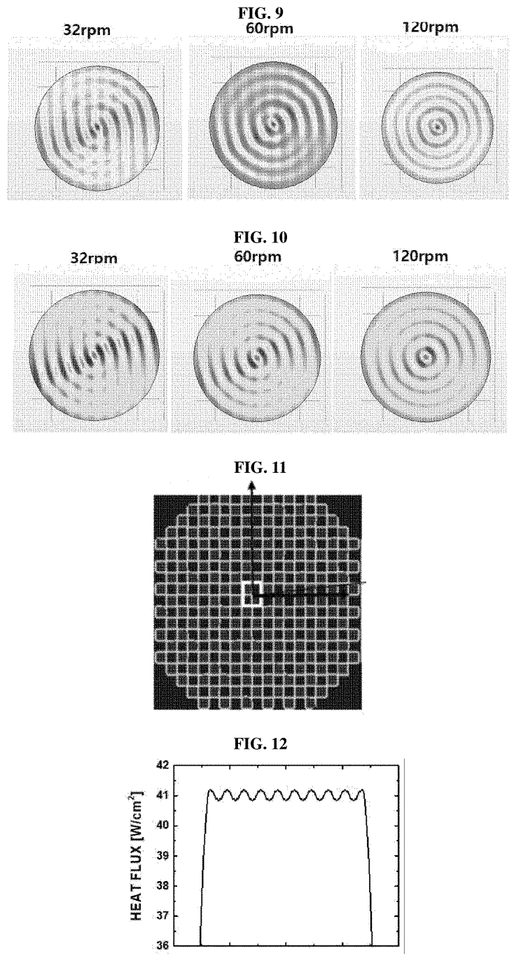

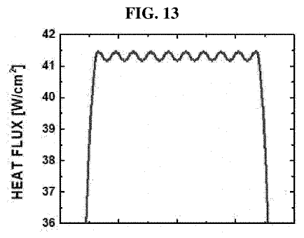

FIG. 6A and FIG. 6B are plane views of the irradiation modules of FIG. 2 mounted on the substrate heat-treating apparatus according to one embodiment of the present disclosure. FIG. 7 shows the evaluation results of heat flux in an axial direction when the flat substrate is stationary in the substrate heat-treating apparatus of FIG. 6A and FIG. 6B. FIG. 8 shows the evaluation results of heat flux when the flat substrate is being rotated in the substrate heat-treating apparatuses of FIG. 6A and FIG. 6B. FIG. 9 shows temperature distribution evaluation results depending on a rotation speed of the flat substrate in the substrate heat-treating apparatus of FIG. 6A. FIG. 10 shows temperature distribution evaluation results depending on a rotation speed of the flat substrate in the substrate heat-treating apparatus of FIG. 6B. FIG. 11 is a plane view of an irradiation module mounted on a substrate heat-treating apparatus according to a comparative example. FIG. 12 shows evaluation results of heat flux in an axial direction when a flat substrate is stationary in the substrate heat-treating apparatus of FIG. 11. FIG. 13 shows evaluation results of heat flux in an axial direction when the flat substrate is being rotated in the substrate heat-treating apparatus provided with the irradiation module according to a comparative example.

In this evaluation, as illustrated in FIG. 6A and FIG. 6B, the evaluation was performed using the substrate heat-treating apparatus provided with the irradiation module according to the embodiment shown in FIG. 2. In addition, as a comparative example, an evaluation for a substrate heat-treating apparatus having an irradiation module according to a conventionally used comparative example, as shown in FIG. 11 was also performed.

The substrate heat-treating apparatus according to the embodiment of the present disclosure used in this evaluation was formed so that the total area of the irradiation module is larger than the area of the wafer. The substrate heat-treating apparatus may be formed such that the terminal region of the irradiation module passes the center of the flat substrate as illustrated in FIG. 6A, and may be formed such that the device region of the irradiation module passes the center of the flat substrate as illustrated in FIG. 6B. In this evaluation, heat flux in the axial direction was evaluated in a state in which the flat substrate was stationary and in a state in which the flat substrate was being rotated.

In addition, in this evaluation, the highest temperature and lowest temperature on the flat substrate, an average temperature, and a temperature difference were evaluated while the flat substrate was heated to near 1,000° C. in a state in which the flat substrate was being rotated.

Referring to FIG. 7, the substrate heat-treating apparatus shows difference in heat flux in the x-axial direction between the device region and the terminal region of the irradiation module in a state in which the flat substrate was stationary. Difference in heat flux in the x-axial direction in the substrate heat-treating apparatus was evaluated to be 1.5%. It is judged that this difference is caused by the device region and the terminal region in the irradiation module. It is judged that this is because, in the irradiation module, the terminal region and the device region are clearly distinguished in the x-axial direction and the length of the terminal region is relatively longer than the width thereof. In contrast, in the substrate heat-treating apparatus, only the device regions are existed in the irradiation module in the y-axial direction of the irradiation module, so there was no difference in heat flux. The above evaluation result was almost the same as those for the irradiation modules of FIG. 6A and FIG. 6B.

Referring to FIG. 8, the substrate heat-treating apparatus shows a relatively uniform heat flux distribution irrespective of the axial direction in a state in which the flat substrate was being rotated, as compared to that in a state in which the flat substrate was stationary.

In addition, difference in heat flux in the substrate heat-treating apparatus was evaluated to be 0.3% regardless of the axial direction. The above evaluation result was almost the same as those for the irradiation modules of FIG. 6A and FIG. 6B.

Referring to FIG. 9, in the substrate heat-treating apparatus including the irradiation module according to FIG. 6A, the highest temperature of the flat substrate was slightly decreased as the rotation speed of the flat substrate was increased, and the lowest temperature was constantly measured. As the rotation speed of the flat substrate was increased to 32 rpm, 60 rpm, and 120 rpm, the highest temperature of the flat substrate was evaluated as 1,017.2° C., 1,017.0° C., and 1,016.9° C., and the lowest temperature was evaluated as 1,015.5° C., so that a temperature deviation was decreased to 1.7° C., 1.5° C., and 1.4° C. On the other hand, in a state in which the flat substrate was stationary, the highest temperature was evaluated as 1,018.1° C. and the lowest temperature was evaluated as 1,015.3° C., so the temperature deviation was 2.8° C., which is an increased value compared to that in a state in which the flat substrate was being rotated.

Referring to FIG. 10, the substrate heat-treating apparatus having the irradiation module according to FIG. 6B exhibits the same trend as the substrate heat-treating apparatus having the irradiation module according to FIG. 6A. However, as the rotation speed of the flat substrate was increased to 32 rpm, 60 rpm, and 120 rpm, the highest temperature of the flat substrate was the same at 1,011.6° C., and the lowest temperature was evaluated as 1,000.1° C., 1,000.2° C., and 1,000.3° C., so that a temperature deviation was decreased to 1.5° C., 1.4° C., and 1.3° C. On the other hand, in a state in which the flat substrate was stationary, the highest temperature was evaluated as 1,001.9° C. and the lowest temperature was evaluated as 999.6° C., so the temperature deviation was 2.3° C., which is an increased value compared to that in a state in which the flat substrate was being rotated. The temperature deviation of the irradiation module shown in FIG. 6B is relatively smaller than that of the irradiation module shown in FIG. 6A. It is judged that this evaluation result is because the irradiation module shown in FIG. 6b is disposed so that the device region passes the center of the flat substrate, and thus the temperature of the central portion is relatively high.

Referring to FIG. 11, in the irradiation module according to the comparative example, the device region and the terminal region have a square shape, and the device region and the terminal region are disposed in a chess shape in which the device region and the terminal region are alternately arranged.

Referring to FIG. 12, in the substrate heat-treating apparatus according to the comparative example, there was difference in heat flux between the device region and the terminal region of the irradiation module in the x-axial direction and the y-axial direction in a state in which the flat substrate was stationary. Difference in heat flux in the x-axial direction and the y-axial direction in the above substrate heat-treating apparatus was equally evaluated as 0.9%. It was evaluated that, in the substrate heat-treating apparatus according to the comparative example, difference in heat flux in the state in which the flat substrate was stationary was smaller than difference in heat flux in the x-axial direction in the substrate heat-treating apparatuses shown in FIGS. 6A and 6B. It is judged that this is because the length of the terminal region is relatively small in the irradiation module according to the comparative example, so the temperature is increased by the adjacent device region.

Referring to FIG. 13, this drawing shows, in the substrate heat-treating apparatus according to the comparative example, relatively low difference in heat flux in a state in which the flat substrate was being rotated, compared to that in a state in which the flat substrate was stationary. However, difference in heat flux of the above substrate heat-treating apparatus is higher than difference in heat flux of the substrate heat-treating apparatus according to FIGS. 6A and 6B.

From the above evaluation, it can be seen that the substrate heat-treating apparatus according to the embodiment of the present disclosure can heat the flat substrate more uniformly when the flat substrate is being rotated.

In order to help those skilled in the art to understand, the most preferred embodiments are selected from the various implementable embodiments of the present disclosure, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

### INDUSTRIAL APPLICABILITY

The substrate heat-treating apparatus using the VCSEL of the present disclosure may heat the flat substrate such as a semiconductor wafer or a glass substrate using a laser irradiated from the VCSEL to heat-treat the flat substrate.

1. A substrate heat-treating apparatus using a VCSEL device, comprising:
a process chamber in which a flat substrate to be heat-treated is placed; and
an irradiation module configured to irradiate a laser beam to the flat substrate, the irradiation module comprising a device array plate and sub-irradiation modules placed on an upper surface of the device array plate, each of sub-irradiation modules including a device region on which the VCSEL device is mounted and a terminal region located a front side or a rear side of the device region,
wherein, in the irradiation module, the device regions and the terminal regions are disposed in a x-axial direction, respectively, and the device regions and the terminal regions are alternately disposed in a y-axial direction perpendicular to the x-axial direction.

2. The substrate heat-treating apparatus using a VCSEL device of claim 1,
wherein, in the sub-irradiation module, the device region is formed in a quadrangular shape and the terminal regions protrude from the other side of a front end and one end side of a rear end of the device region, respectively,
wherein, in the irradiation module, the device regions and the terminal regions are sequentially disposed in the x-axial direction, respectively, and the device regions and the terminal regions are alternately disposed in the y-axial direction.

3. The substrate heat-treating apparatus using a VCSEL device of claim 1,
wherein, in the sub-irradiation module, the device region is formed in a quadrangular shape and the terminal region is formed at the entire front end of the device region,
wherein, in the irradiation module, the device regions and the terminal regions are sequentially disposed in the x-axial direction, respectively, and the device regions and the terminal regions are alternately disposed in the y-axial direction.

4. The substrate heat-treating apparatus using a VCSEL device of claim 1,
wherein the sub-irradiation module is formed in a quadrangular shape, the terminal regions are formed on the other side of the front end and one side of the rear end of the quadrangular shape, respectively, and have a rectangular shape having a predetermined length and a width corresponding to half the entire width of the sub-irradiation module, the device region is formed on a region excluding the terminal regions,
wherein the irradiation module comprises a region in which the device regions and the terminal regions are alternately arranged in the x-axial direction and a region in which only the device regions are arranged, and the device regions and the terminal regions are alternately arranged in the y-axial direction.

5. The substrate heat-treating apparatus using a VCSEL device of claim 1, wherein the sub-irradiation modules are formed to be independently supplied with power.

6. The substrate heat-treating apparatus using a VCSEL device of claim 1, wherein the sub-irradiation module comprises a device substrate on which the VCSEL device and an electrode terminal are mounted, and a cooling block coupled to a lower portion of the device substrate to cool the device substrate and the VCSEL device, wherein the cooling block has a cooling passage, through which cooling water flows, formed therein.

7. The substrate heat-treating apparatus using a VCSEL device of claim 1,
wherein the process chamber comprises an outer housing, an inner housing disposed inside the outer housing and formed to have a height smaller than that of the outer housing, a beam transmitting plate placed above the inner housing, and a lower plate coupled to lower sides of the outer housing and the inner hosing,
wherein the process chamber has an upper accommodation space formed inside the outer housing and above the inner housing to provide a space in which the flat substrate is placed, and a lower accommodation space formed between an outer surface of the inner housing and an inner surface of the outer housing,
wherein the irradiation module is positioned below the beam transmitting plate to irradiate a laser beam to a lower surface of the flat substrate.

8. The substrate heat-treating apparatus using a VCSEL device of claim 7,
wherein the process chamber further comprises a substrate support supporting an outer side of the flat substrate and formed to extend into the lower accommodation space,
wherein the substrate heat-treating apparatus further comprises a substrate rotating module having an inner rotating means having a ring shape in which N poles and S poles are alternately arranged in a circumferential direction and being coupled to a lower portion of the substrate support within the lower accommodation space, and an outer rotating means placed outside the outer housing to face the inner rotating means and configured to generate a magnetic force to rotate the inner rotating means.

9. The substrate heat-treating apparatus using a VCSEL device of claim 1, wherein the substrate heat-treating apparatus further comprises a substrate rotating module configured to support and rotate the flat substrate.

10. The substrate heat-treating apparatus using a VCSEL device of claim 1, wherein the irradiation module is formed such that the device region is located at a center of the flat substrate.

11. The substrate heat-treating apparatus using a VCSEL device of claim 1, wherein the irradiation module is formed such that the terminal region is located at a center of the flat substrate.

12. A substrate heat-treating apparatus using a VCSEL device, comprising:
a process chamber in which a flat substrate is placed; and
an irradiation module comprising a device array plate and sub-irradiation modules placed on an upper surface of the device array plate, each of sub-irradiation modules including a device region on which the VCSEL device is mounted and a terminal region located a front side or a rear side of the device region,
wherein, in the irradiation module, the device regions and the terminal regions are disposed in a x-axial direction, respectively, and the device regions and the terminal regions are alternately disposed in a y-axial direction perpendicular to the x-axial direction.

13. The substrate heat-treating apparatus using a VCSEL device of claim 12,
wherein, in the sub-irradiation module, the device region is formed in a quadrangular shape and the terminal regions protrude from the other side of a front end and one end side of a rear end of the device region, respectively,
wherein, in the irradiation module, the device regions and the terminal regions are sequentially disposed in the x-axial direction, respectively, and the device regions and the terminal regions are alternately disposed in the y-axial direction.

14. The substrate heat-treating apparatus using a VCSEL device of claim 12,
wherein, in the sub-irradiation module, the device region is formed in a quadrangular shape and the terminal region is formed at the entire front end of the device region,
wherein, in the irradiation module, the device regions and the terminal regions are sequentially disposed in the x-axial direction, respectively, and the device regions and the terminal regions are alternately disposed in the y-axial direction.

15. The substrate heat-treating apparatus using a VCSEL device of claim 12,
wherein the sub-irradiation module is formed in a quadrangular shape, the terminal regions are formed on the other side of the front end and one side of the rear end of the quadrangular shape, respectively, and have a rectangular shape having a predetermined length and a width corresponding to half the entire width of the sub-irradiation module, the device region is formed on a region excluding the terminal regions,
wherein the irradiation module comprises a region in which the device regions and the terminal regions are alternately arranged in the x-axial direction and a region in which only the device regions are arranged, and the device regions and the terminal regions are alternately arranged in the y-axial direction.

16. The substrate heat-treating apparatus using a VCSEL device of claim 12, wherein the sub-irradiation modules are formed to be independently supplied with power.

17. The substrate heat-treating apparatus using a VCSEL device of claim 1, wherein the sub-irradiation module comprises a device substrate on which the VCSEL device and an electrode terminal are mounted, and a cooling block coupled to a lower portion of the device substrate to cool the device substrate and the VCSEL device, wherein the cooling block has a cooling passage, through which cooling water flows, formed therein.

18. The substrate heat-treating apparatus using a VCSEL device of claim 12,
wherein the process chamber comprises an outer housing, an inner housing disposed inside the outer housing and formed to have a height smaller than that of the outer housing, a beam transmitting plate placed above the inner housing, and a lower plate coupled to lower sides of the outer housing and the inner hosing,
wherein the process chamber has an upper accommodation space formed inside the outer housing and above the inner housing to provide a space in which the flat substrate is placed, and a lower accommodation space formed between an outer surface of the inner housing and an inner surface of the outer housing,
wherein the irradiation module is positioned below the beam transmitting plate to irradiate a laser beam to a lower surface of the flat substrate.

19. The substrate heat-treating apparatus using a VCSEL device of claim 18,
wherein the process chamber further comprises a substrate support supporting an outer side of the flat substrate and formed to extend into the lower accommodation space,
wherein the substrate heat-treating apparatus further comprises a substrate rotating module having an inner rotating means having a ring shape in which N poles and S poles are alternately arranged in a circumferential direction and being coupled to a lower portion of the substrate support within the lower accommodation space, and an outer rotating means placed outside the outer housing to face the inner rotating means and configured to generate a magnetic force to rotate the inner rotating means.

20. The substrate heat-treating apparatus using a VCSEL device of claim 12, wherein the substrate heat-treating apparatus further comprises a substrate rotating module configured to support and rotate the flat substrate.
